(19) United States
(12) Patent Application Publication
(10) Pub. No.: US 2026/0271774 A1
(43) Pub. Date: Sep. 10, 2026

(54) SEMICONDUCTOR PACKAGE MODULE AND METHOD OF MANUFACTURING THE SAME

(71) Applicant: POWERTECH TECHNOLOGY INC., Hsinchu County (TW)

(72) Inventors: Chih Hao CHEN, Hsinchu County (TW); Shang-Yu CHANG CHIEN, Hsinchu County (TW)

(21) Appl. No.: 19/555,908

(22) Filed: Mar. 4, 2026

(30) Foreign Application Priority Data
Mar. 4, 2025 (TW) 114107963

(51) Int. Cl. H10W 74/10; H10W 70/08; H10W 70/65; H10W 74/01

(52) U.S. Cl. CPC H10W 74/127; H10W 70/08; H10W 70/657; H10W 74/012

(57) ABSTRACT

A semiconductor package module includes two redistribution layers, two electronic components, an adhesive material, an encapsulation layer and conductive pillars. The electronic components are located between two redistribution layers. The adhesive material is disposed between the electronic components. The electronic components and the adhesive material are stacked on each other in the normal direction of one of the redistribution layers, and the active surfaces of the electronic components face the redistribution layers separately. The encapsulation layer is disposed between two redistribution layers and encapsulates the electronic components. The conductive pillar is connected to the redistribution layers and extends from one redistribution layer to the other redistribution layer through the encapsulation layer. The first part and the second part of the conductive pillar are connected to two redistribution layers separately. The interface between the first part and the second part is flush with the plane of the adhesive material.

This application claims priority to Taiwan Application Serial Number 114107963, filed March 4, 2025, which is herein incorporated by reference in its entirety.

### BACKGROUND

### Technical Field

The present disclosure relates to a semiconductor package module and a method of manufacturing the same.

### Description of Related Art

The conventional mobile device and wearable device, such as a laptop, a smartphone, and a smart watch, develop into a trend of reducing size (e.g., volume). However, the sizes of these electronic devices (i.e., the previous mobile device and wearable device) are limited by the size of a semiconductor package module inside the electronic device. In order to meet the previous trend of reducing the sizes of the mobile device and the wearable device, it is necessary to improve the inside design of the existing semiconductor package module.

### SUMMARY

At least one embodiment according to the present disclosure provides a semiconductor package module which can help to reduce the sizes (e.g., volumes) of the mobile device and the wearable device.

At least one embodiment according to the present disclosure further provides a method of manufacturing the above semiconductor package module.

At least one embodiment of the disclosure provides a semiconductor package module including a first redistribution layer, a first electronic component, an adhesive material, a second electronic component, a second redistribution layer, an encapsulation layer, and a conductive pillar. The first electronic component is disposed on the first redistribution layer and has a first surface away from the first redistribution layer. The adhesive material is disposed on the first surface of the first electronic component. The second electronic component is disposed on the adhesive material, while the first electronic component is disposed between the first redistribution layer and the second electronic component. The first electronic component, the adhesive material, and the second electronic component are stacked on each other in a normal direction of the first redistribution layer. The second redistribution layer is disposed on the second electronic component, while the first electronic component and the second electronic component are located between the first redistribution layer and the second redistribution layer. An active surface of the first electronic component and an active surface of the second electronic component face the first redistribution layer and the second redistribution layer respectively. The encapsulation layer disposed between the first redistribution layer and the second redistribution layer encapsulates the first electronic component and the second electronic component. The conductive pillar is connected to the first redistribution layer and the second redistribution layer, and extends from the first redistribution layer to the second redistribution layer through the encapsulation layer. A first part of the conductive pillar is connected to the first redistribution layer, while a second part of the conductive pillar is connected to the second redistribution layer. An interface between the first part and the second part is flush with a plane of the adhesive material.

At least one embodiment of the disclosure provides a method of manufacturing the semiconductor package module including: providing a holding board; forming at least one first conductive pillar on the holding board; disposing at least one first electronic component on the holding board, where a first surface of the first electronic component is connected to the holding board; after forming the first conductive pillar and disposing the first electronic component, forming a first encapsulation layer on the holding board, where the first encapsulation layer encapsulates the first conductive pillar and the first electronic component, and exposes a first end surface of the first conductive pillar; after forming the first encapsulation layer, disposing a first redistribution layer on the first end surface of the first conductive pillar, where the first redistribution layer is electrically connected to the first electronic component, and the first conductive pillar has an interface away from the first redistribution layer; after disposing the first redistribution layer, removing the holding board, so as to expose the first surface of the first electronic component and expose the interface of the first conductive pillar; after removing the holding board, forming a second conductive pillar on the interface of the first conductive pillar; disposing an adhesive material on a second surface of a second electronic component; after forming the second conductive pillar, disposing the second electronic component on the first surface of the first electronic component, so that the first electronic component, the adhesive material, and the second electronic component are stacked on each other in a normal direction of the first redistribution layer, while the adhesive material is located between the first electronic component and the second electronic component; after disposing the second electronic component, forming a second encapsulation layer on the first encapsulation layer, where the second encapsulation layer encapsulates the second conductive pillar and the second electronic component, and exposes a second end surface of the second conductive pillar; and after forming the second encapsulation layer, disposing a second redistribution layer on the second end surface of the second conductive pillar, where the second redistribution layer is electrically connected to the second electronic component. An active surface of the first electronic component and an active surface of the second electronic component face the first redistribution layer and the second redistribution layer respectively.

Based on the above, the first electronic component and the second electronic component are disposed between the first redistribution layer and the second redistribution layer in a back-to-back stack (i.e., the active surfaces of both the first electronic component and the second electronic component are arranged back to back to each other). The first redistribution layer and the second redistribution layer are electrically connected to each other via the conductive pillar. As a result, the planar size (i.e., the size of x-y plane, for example, area) of the semiconductor package module can be reduced, so as to help to meet the trend of reducing the sizes (e.g., volumes) of the existing mobile device and the wearable device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows.

FIG. 1 is a cross-sectional view of a semiconductor package module according to at least one embodiment of this disclosure.

FIG. 2 is a cross-sectional view of a semiconductor package module according to at least one embodiment of this disclosure.

FIG. 3 is a cross-sectional view of a semiconductor package module according to at least one embodiment of this disclosure.

FIGS. 4A to 4G are cross-sectional views of a method of manufacturing the semiconductor package module in FIG. 1.

FIGS. 5A to 5C are cross-sectional views of a method of manufacturing the semiconductor package module according to at least one embodiment of this disclosure.

FIG. 6 is cross-sectional views of a method of manufacturing the semiconductor package module in FIG. 3.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

Moreover, the words, such as “about”, “approximately”, or “substantially”, appearing in the present disclosure not only cover the clearly stated values and ranges, but also include permissible deviation ranges as understood by those with ordinary knowledge in the technical field. The permissible deviation range can be caused by the error generated during the measurement, where the error is caused by such as the limitation of the measurement system or the process conditions. In addition, “about” may be expressed within one or more standard deviations of the values, such as within ±30%, ±20%, ±10%, or ±5%. The word “about”, “approximately” or “substantially” appearing in this text can choose an acceptable deviation range or a standard deviation according to optical properties, etching properties, mechanical properties or other properties, not just one standard deviation to apply all the optical properties, etching properties, mechanical properties and other properties.

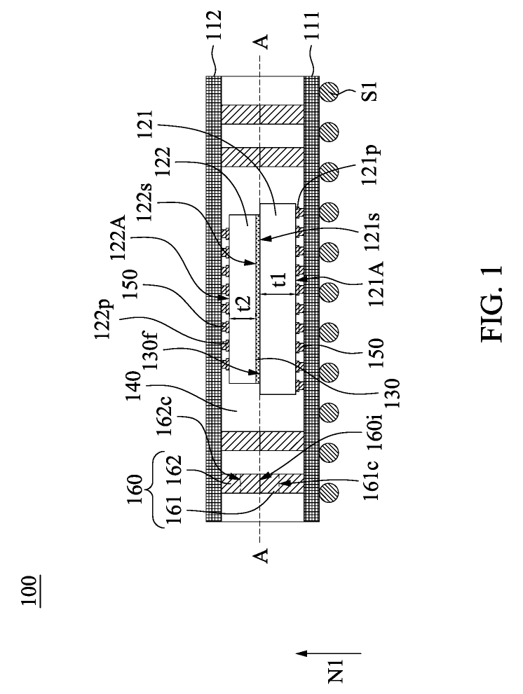

FIG. 1 is a cross-sectional view of a semiconductor package module 100 according to at least one embodiment of this disclosure. Referring to FIG. 1, the semiconductor package module 100 includes a first redistribution layer 111, a second redistribution layer 112, a first electronic component 121, a second electronic component 122, an adhesive material 130, an encapsulation layer 140, and at least one conductive pillar 160. It is noted that the semiconductor package module 100 as shown in the embodiment of FIG. 1 includes multiple conductive pillars 160, but the semiconductor package module 100 may include only one conductive pillar 160 in another embodiment.

The first electronic component 121 is disposed on the first redistribution layer 111 and has a first surface 121s away from the first redistribution layer 111. The adhesive material 130 is disposed on the first surface 121s of the first electronic component 121, while the second electronic component 122 is disposed on the adhesive material 130. The first electronic component 121 is located between the first redistribution layer 111 and the second electronic component 122, while the first electronic component 121, the adhesive material 130, and the second electronic component 122 are stacked on each other in a normal direction N1 of the first redistribution layer 111, where the normal direction N1 is a vertical direction as shown in FIG. 1, and each of the conductive pillars 160 can extend in the normal direction N1.

As shown in FIG. 1, the second redistribution layer 112 is disposed on the second electronic component 122, while the first electronic component 121 and the second electronic component 122 are located between the first redistribution layer 111 and the second redistribution layer 112. The second electronic component 122 has a second surface 122s away from the second redistribution layer 112. It is particular to noted that an active surface 121A (i.e., the surface opposite to the first surface 121s) of the first electronic component 121 and an active surface 122A (i.e., the surface opposite to the second surface 122s) of the second electronic component 122 face the first redistribution layer 111 and the second redistribution layer 112 respectively. In other words, the first surface 121s of the first electronic component 121 is arranged to face the second surface 122s of the second electronic component 122.

The first electronic component 121 and the second electronic component 122 further include a plurality of pads 121p and 122p respectively. These pads 121p and 122p are located on the active surface 121A of the first electronic component 121 and the active surface 122A of the second electronic component 122. The first electronic component 121 and the second electronic component 122 are connected to the first redistribution layer 111 and the second redistribution layer 112 respectively via the pads 121p and 122p.

The semiconductor package module 100 further includes a plurality of conductive structures 150, where these conductive structures 150 are disposed on the pads 121p and 122p respectively. These pads 121p and 122p are electrically connected to the first redistribution layer 111 and the second redistribution layer 112 via the conductive structures 150. Specifically, taking FIG. 1 for example, the first electronic component 121 can be bonded to the first redistribution layer 111 and electrically connected to the first redistribution layer 111 via the conductive structures 150. On the other hand, the second electronic component 122 also can be bonded to the second redistribution layer 112 and electrically connected to the second redistribution layer 112 via the conductive structures 150.

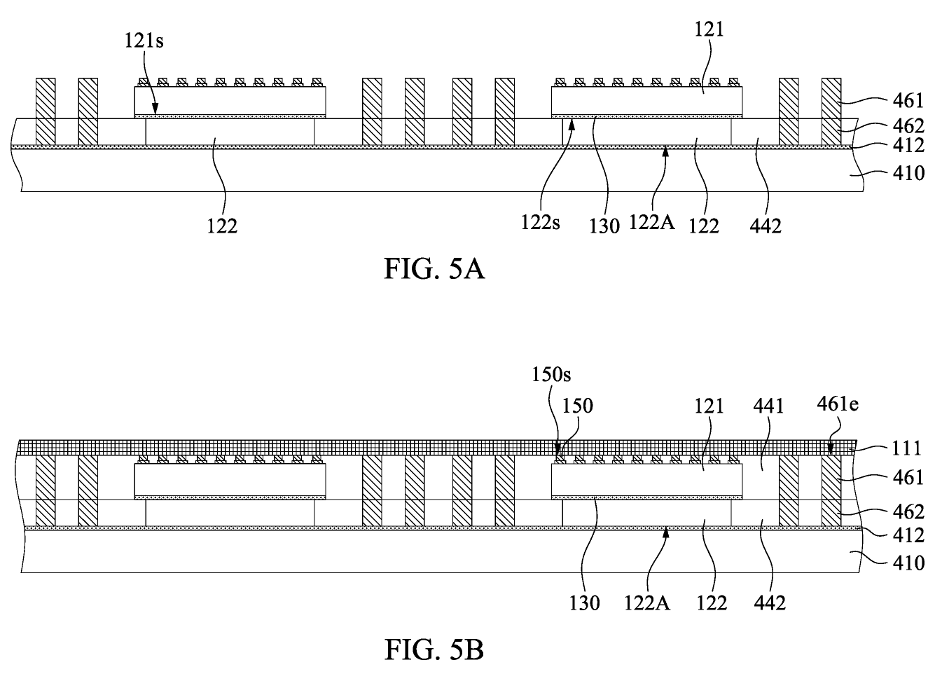

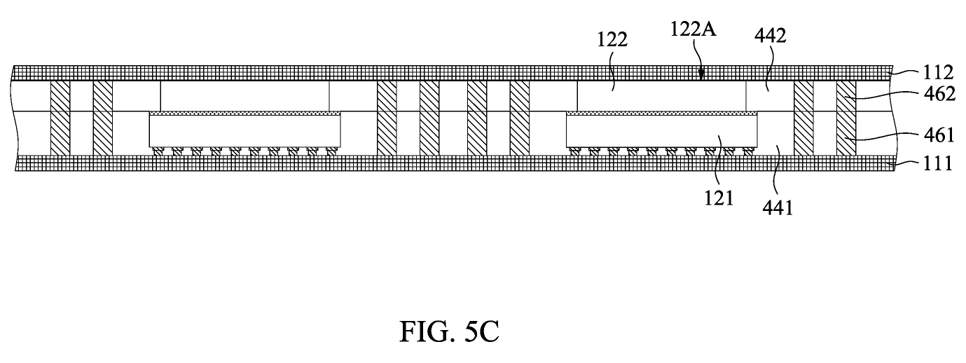

In the present embodiment, the conductive structures 150 may be, but are not limited to, bumps or solder balls. In addition, in some embodiments, there also may be no conductive structure 150 formed between the first electronic component 121 and the first redistribution layer 111 (or between the second electronic component 122 and the second redistribution layer 112). That is, the first electronic component 121 or the second electronic component 122 can be bonded to the first redistribution layer 111 or the second redistribution layer 112 by bump-free. As shown in FIG. 5C, the electrical transmission between an electronic component and a redistribution layer (e.g., between the second electronic component 122 and the second redistribution layer 112) can be improved by the mounting of bump-free.

In addition, under the condition that the thickness of the semiconductor package module 100 is not changed, the thickness saved by bump-free can be added to the thickness of the first electronic component 121 or the second electronic component 122, that is, the thicker first electronic component 121 or second electronic component 122 can be employed, so that the risk of damaging the first electronic component 121 or the second electronic component 122 during die bonding can be reduced, thereby improving process yield.

On the other hand, when the thickness of the semiconductor package module 100 is reduced due to no bump (i.e., conductive structures 150), the thickness (i.e., height) of the conductive pillar 160 also will be reduced. Generally speaking, the conductive pillar 160 can be formed by lithography and electroplating, so the thicker the conductive pillar 160 is, the harder the formation of the conductive pillar 160 is, and the higher the risk of manufacture is. Hence, when the thickness of the conductive pillar 160 is reduced, it is advantageous to reduce the risk and difficulty of forming the conductive pillar 160 and thus to improve the manufacture of semiconductor package module 100.

Any one of the first electronic component 121 and the second electronic component 122 may be a packaged chip or an unpackaged die. Moreover, the first electronic component 121 and the second electronic component 122 each may be a logic chip, such as microcontroller unit (MCU), but the kind of the first electronic component 121 and the second electronic component 122 in the present disclosure is not limited to the above logic chip.

In the embodiment as shown in FIG. 1, the semiconductor package module 100 includes one first electronic component 121 and one second electronic component 122. However, there may be at least one first electronic component 121 and at least one second electronic component 122 in a single semiconductor package module of another embodiment. In other words, the number of each of the first electronic component 121 and the second electronic component 122 may be at least one, such as two. That is, the total number of both the first electronic component 121 and the second electronic component 122 may be four. Hence, FIG. 1 does not limit the number of both the first electronic component 121 and the second electronic component 122.

It is particular to note that in the embodiment of FIG. 1, the adhesive material 130 which is connected to the first electronic component 121 and the second electronic component 122 may be a die attach film (DAF).

The encapsulation layer 140 disposed between the first redistribution layer 111 and the second redistribution layer 112 covers the first electronic component 121 and the second electronic component 122. It is particular to note that the encapsulation layer 140 partially covers the active surface 121A of the first electronic component 121, and partially covers the active surface 122A of the second electronic component 122. That is, the encapsulation layer 140 incompletely covers the active surface 121A, so as to allow the electrical connection between the first electronic component 121 and the first redistribution layer 111. The encapsulation layer 140 also incompletely covers the active surface 122A, so as to allow the electrical connection between the second electronic component 122 and the second redistribution layer 112. The encapsulation layer 140 may include solid molding compound or similar molding material, for example.

On the other hand, the encapsulation layer 140 further encapsulates the conductive pillar 160. Specifically, the conductive pillar 160 is connected to the first redistribution layer 111 and the second redistribution layer 112, and extends from the first redistribution layer 111 to the second redistribution layer 112 through the encapsulation layer 140. The conductive pillar 160 has a first part 161 and a second part 162, in which the first part 161 of the conductive pillar 160 is connected to the first redistribution layer 111, while the second part 162 of the conductive pillar 160 is connected to the second redistribution layer 112. As shown by the line A-A in FIG. 1, an interface 160i existing between the first part 161 and the second part 162 is flush with a plane 130f of the adhesive material 130.

Specifically, the first part 161 of the conductive pillar 160 has a first section 161c, while the second part 162 of the conductive pillar 160 has a second section 162c. It is worth mentioning that in some embodiments, the area of the first section 161c and the area of the second section 162c may be not equal, while the area of the first section 161c can be greater or less than the area of the second section 162c. In addition, in other embodiment, the sizes (e.g., width or volume) of both the first part 161 and the second part 162 in one single conductive pillar 160 may be different.

However, the present disclosure is not limited to the above. In some embodiments, the area of the first section 161c and the area of the second section 162c may be equal. Furthermore, the materials for the formation of the first part 161 and the second part 162 may be the same or different. For example, any one of the first part 161 and the second part 162 includes a single layer structure or a multilayer structure, while the previous materials may include such as copper, aluminum, nickel, titanium, tin, silver, other suitable materials, alloys of at least two of the above, or combinations thereof. It is worth mentioning that regardless of whether the materials of the first part 161 and the second part 162 are the same or different, the interface (boundary) 160i will exist between the first part 161 and the second part 162.

In the embodiment as shown in FIG. 1, the area of the second surface 122s of the second electronic component 122 is less than the area of the first surface 121s of the first electronic component 121, but the present disclosure is not limited thereto. In other embodiment of the present disclosure, the area of the second surface 122s of the second electronic component 122 also may be equal to (i.e., the first electronic component 121 and the second electronic component 122 overlap in the normal direction N1) or greater than the area of the first surface 121s of the first electronic component 121.

In addition, in order to prevent the warpage due to a large difference in the coefficient of thermal expansion between the adhesive material 130 and the encapsulation layer 140, it is necessary to reduce the contact area between the adhesive material 130 and the encapsulation layer 140. Hence, in the embodiment, the adhesive material 130 completely covers the second surface 122s of the second electronic component 122, but does not cover a zone of the first surface 121s of the first electronic component 121.

On the other hand, the sizes (e.g., volume or thickness) of both the first electronic component 121 and the second electronic component 122 may be different. For example, in the present embodiment, the thickness t1 of the first electronic component 121 can be thicker than the thickness t2 of the second electronic component 122. Moreover, the thickness t1 of the first electronic component 121 can range between 60µm and 100µm, while the thickness t2 of the second electronic component 122 can range between 50µm and 80µm, but the present disclosure is not limited thereto. In other embodiment, the thickness t1 of the first electronic component 121 also can be thinner or equal to the thickness t2 of the second electronic component 122.

The semiconductor package module 100 further includes a plurality of solder balls S1 connected to the first redistribution layer 111. By using these solder balls S1, the semiconductor package module 100 can be mounted to a circuit substrate, so that the semiconductor package module 100 is electrically connected to the circuit substrate. The circuit substrate may be a packaged substrate with an integrated circuit (IC), a printed circuit board (PCB), or other suitable outer device.

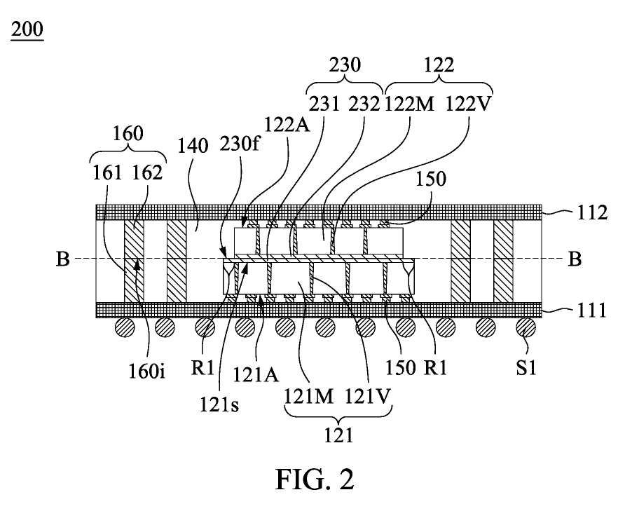

Reference is made to a semiconductor package module 200 according to another embodiment of the disclosure in FIG. 2. The semiconductor package module 200 is substantially similar to the semiconductor package module 100, where the difference between them is that the adhesive material 230 of the semiconductor package module 200 further includes a first adhesive layer 231 and a second adhesive layer 232. The first adhesive layer 231 is disposed on the first electronic component 121, and the second adhesive layer 232 is disposed on the second electronic component 122 and between the first adhesive layer 231 and the second electronic component 122.

It is worth mentioning that the first adhesive layer 231 and the second adhesive layer 232 are connected by metallic bonding (metallic bonding), such as eutectic bonding. Specifically, the first adhesive layer 231 and the second adhesive layer 232 can be metallic materials with low temperature eutectic system, such as gold-indium alloy, bronze, gold-tin alloy or the like. As a result, after heating in the temperature range from 156℃ to280℃, a eutectic reaction will occur between the first adhesive layer 231 and the second adhesive layer 232 which are in contact with each other, so as to connect the first adhesive layer 231 and the second adhesive layer 232, and to cause that the first adhesive layer 231 can be electrically connected to the second adhesive layer 232.

As shown in FIG. 2, the first electronic component 121 of the semiconductor package module 200 further includes a plurality of first conductive through holes 121V, while the second electronic component 122 further includes a plurality of second conductive through holes 122V. The first conductive through holes 121V are located in the inside of the first electronic component 121, where the first electronic component 121 is electrically connected to the adhesive material 230 via these first conductive through holes 121V. In particular, the first conductive through holes 121V extend form the active surface 121A of the first electronic component 121 to the first adhesive layer 231 through the main body 121M of the first electronic component 121.

On the other hand, the second conductive through holes 122V are located in the inside of the second electronic component 122, where the second electronic component 122 is electrically connected to the adhesive material 230 via these second conductive through holes 122V. In particular, the second conductive through holes 122V extend from the active surface 122A of the second electronic component 122 to the second adhesive layer 232 through the main body 122M of the second electronic component 122. The first conductive through holes 121V and the second conductive through holes 122V can be formed by through silicon via (TSV), for example.

By the arrangement of the first conductive through holes 121V and the second conductive through holes 122V, the semiconductor package module 200 can be more flexible in layout design (e.g., ground/power wiring arrangements). In other words, the electrical connection between the second electronic component 122 and the first redistribution layer 111 is not limited to using the conductive pillar 160.

In the present embodiment, the second electronic component 122 can be electrically connected to the first redistribution layer 111 via the adhesive material 230 and the first electronic component 121. Hence, the number of the conductive pillar 160 in the semiconductor package module 200 can decrease, thereby reducing the size (e.g., volume or area) of the semiconductor package module 200, especially reducing the size of the semiconductor package module 200 on x-y plane, where the x-y plane is, for example, a horizontal plane in FIG. 2, while Z-axis direction is, for example, a vertical direction in FIG. 2.

Referring to FIG. 2, as shown by a line B-B, the interface 160i existing between the first part 161 and the second part 162 both of the conductive pillar 160 is flush with a plane 203f of the adhesive material 230. The adhesive material 230 (i.e., the first adhesive layer 231) completely covers the first surface 121s of the electronic component 121, while the second electronic component 122 does not cover a zone R1 of the plane 230f of the adhesive material 230. It is particular to note that the encapsulation layer 140 in the semiconductor package module 200 directly touches the zone R1 of the adhesive material 230.

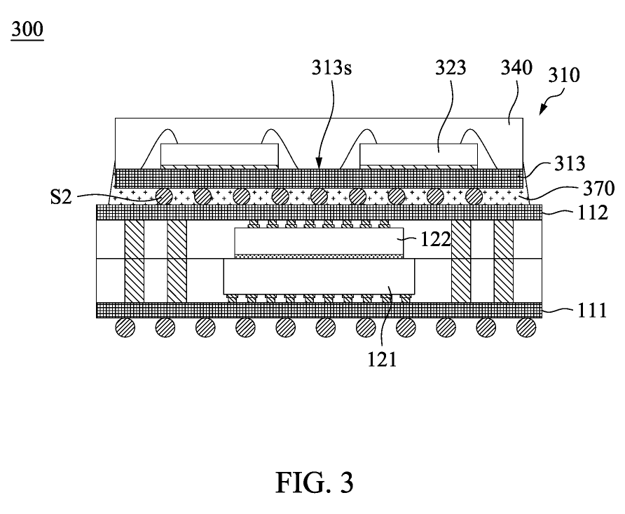

Reference is made to a semiconductor package module 300 according to another embodiment of the disclosure in FIG. 3. The semiconductor package module 300 is substantially similar to the semiconductor package module 100, where the difference between them is that the semiconductor package module 300 further includes at least one electronic packaging unit 310, and the electronic packaging unit 310 may be such as multi-chip package (MCP) or the like. Specifically, the electronic packaging unit 310 includes a wiring substrate 313, at least one chip 323, and an encapsulation layer 340. The wiring substrate 313 of the electronic packaging unit 310 is disposed between the chip 323 and the second redistribution layer 112, and electrically connected to the second redistribution layer 112 via a plurality of solder balls S2, where the electronic packaging unit 310 and the second electronic component 122 are located at two opposite sides of the second redistribution layer 112.

The chip 323 can be electrically connected to the wiring substrate 313 by flip-chip or wire bonding. In this embodiment, the chip 323 may be an active chip or a passive chip, for example. Alternatively, the chip 323 may include the active chip and the passive chip, but is not limited thereto.

The encapsulation layer 340 is disposed on the surface 313s of the wiring substrate 313 and encapsulates the chip 323. A filler 370 is disposed between the second redistribution layer 112 and the wiring substrate 313 of the electronic packaging unit 310, while the filler 370 can encapsulate the solder balls S2, to enhance the bonding strength between the wiring substrate 313 and the second redistribution layer 112. The filler 370 may be, for example, capillary underfill (CUF), non-conductive film (NCF), or other suitable filling material, which does not limit the disclosure.

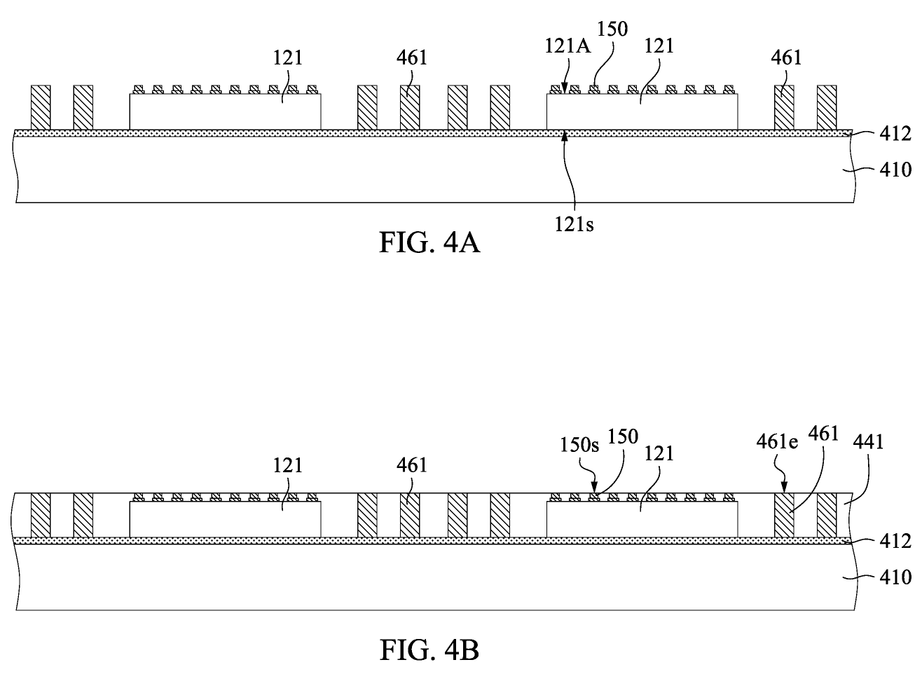

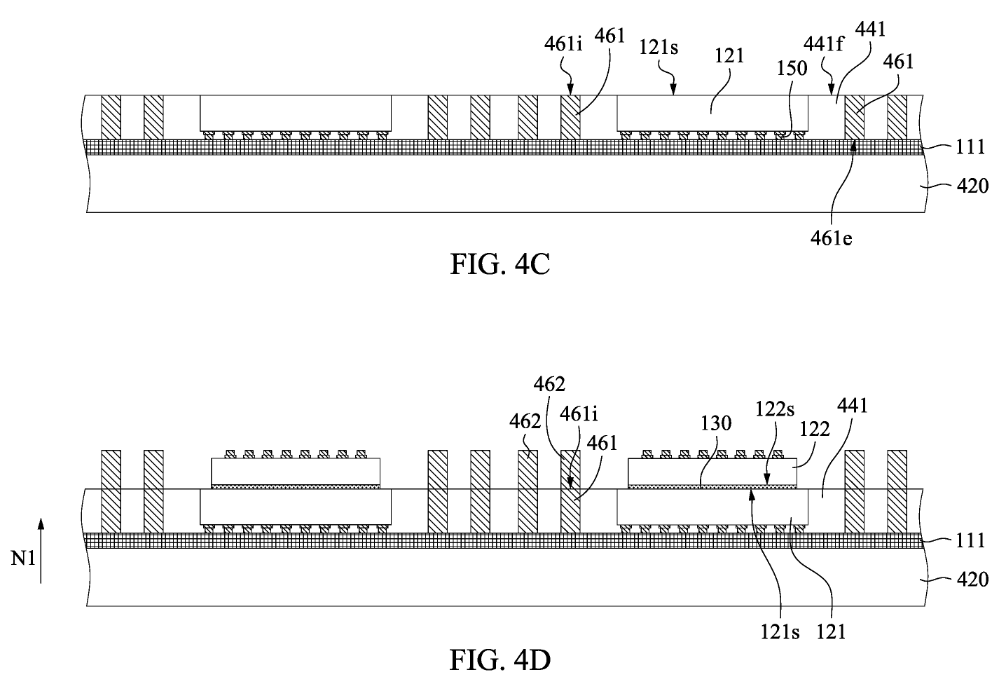

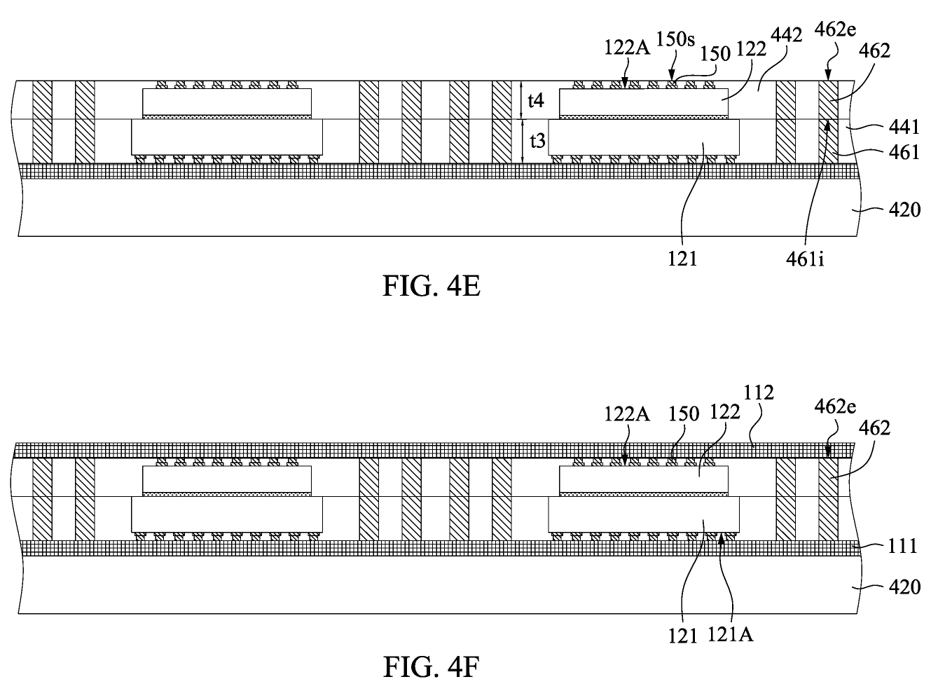

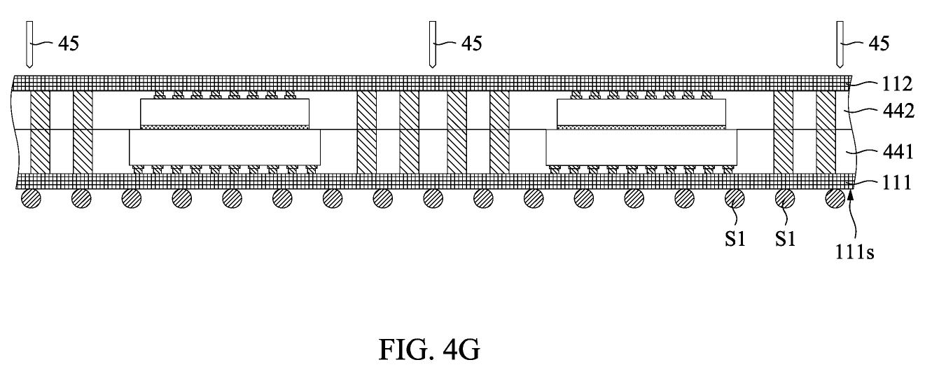

FIGS. 4A to 4G are cross-sectional views of a method of manufacturing the semiconductor package module in FIG. 1. Referring to FIG. 4A, first, a holding board 410 is provided. The holding board 410 may be a rigid substrate, for example, glass board, metal board, or ceramic board. In some embodiment, a release layer 412 can be disposed on one of the sides of the holding board 410. Next, at least one first conductive pillar 461 is formed on the side (where the release layer 412 is formed) of the holding board 410. The first conductive pillar 461 may include copper, aluminum, nickel, titanium, tin, silver, other suitable materials or combinations thereof, and may be a conductive pillar formed by lithography, electroplating, or photoresist stripping, for example, which the disclosure does not limit. The first conductive pillar 461 may be formed of other suitable material and by other formation depending on actual design requirements.

On the other hand, in the step of FIG. 4A, at least one first electronic component 121 can be disposed on the holding board 410 (and on the side where the release layer 412 is formed), and the first surface 121s of the first electronic component 121 bonds to the holding board 410 via an adhesive layer (e.g., DAF, not shown) that is formed between the release layer 412 and the first electronic component 121. It is particular to note that after or before the first electronic component 121 is disposed on the holding board 410, conductive structures 150 can be disposed on the active surface 121A of the first electronic component 121.

Referring to FIG. 4B, after forming the first conductive pillar 461 and disposing the first electronic component 121, a first encapsulation layer 441 is formed on the holding board 410 (and on the side where the release layer 412 is formed). The first encapsulation layer 441 encapsulates the first conductive pillar 461 and the first electronic component 121, and exposes the first end surface 461e of the first conductive pillar 461. In particular, a molding compound (not shown) is disposed on the holding board 410 and, then cured. The molding compound covers the first electronic component 121 and the first conductive pillar 461. Next, the molding compound is grinded from its upper surface, so as to form a first encapsulation layer 441 that exposes the first end surface 461e. This step of grinding can further cause to expose the surface 150s of the conductive structures 150 and cause that the first end surface 461e of the first conductive pillar 461 is flush with the surface 150s of the conductive structures 150.

Referring to FIGS. 4B and 4C, after forming the first encapsulation layer 441, a first redistribution layer 111 is disposed on the first end surface 461e of the first conductive pillar 461, where the first redistribution layer 111 is electrically connected to the first electronic component 121 via the conductive structures 150. The formation of the first redistribution layer 111 can include the following steps: before removing the holding board 410, the first redistribution layer 111 is disposed on the first end surface 461e of the first conductive pillar 461 at first, where the first redistribution layer 111 covers the first encapsulation layer 441, the first conductive pillar 461, and the first electronic component 121. Next, the holding board 420 is attached to the first redistribution layer 111 by an adhesive layer (not shown) formed on a release layer (not shown), or a temporary bonding material, so that the first redistribution layer 111 is located between the holding board 420 and the first electronic component 121.

Next, the holding board 410 is removed after inverting the holding board 410, the first redistribution layer 111, and the holding board 420, so as to expose the first surface 121s of the first electronic component 121, the interface 461i of the first conductive pillar 461, and the plane 441f of the first encapsulation layer 441, as shown in FIG. 4C, where the plane 441f, the first surface 121s of the first electronic component 121, and the interface 461i of the first conductive pillar 461 are coplanar to each other.

Referring to FIG. 4D, after removing the holding board 410 (as shown in FIG. 4B), a second conductive pillar 462 can be formed on the interface 461i of the first conductive pillar 461 by lithography or electroplating. On the other hand, an adhesive material 130 is disposed on the second surface 122s of the second electronic component 122. After forming the second conductive pillar 462, the second electronic component 122 is disposed on the first surface 121s of the first electronic component 121, so that the first electronic component 121, the adhesive material 130, and the second electronic component 122 are stacked on each other in the normal direction N1 of the first redistribution layer 111, where the adhesive material 130 is located between the first electronic component 121 and the second electronic component 122.

It is worth mentioning that in another embodiment of the present disclosure, for example, in the method of manufacturing the semiconductor package module 200 of FIG. 2, the method disclosed in FIG. 2 further includes: disposing an adhesive layer (i.e., the first adhesive layer 231 in FIG. 2) on the first surface 121s of the first electronic component 121 before the second electronic component 122 is disposed on the first electronic component 121, where the adhesive layer contains metal. In this embodiment, the adhesive material (i.e., the second adhesive layer 232 in FIG. 2) disposed on the second surface 122s of the second electronic component 122 also contains metal. Next, the adhesive layer on the first electronic component 121 directly touches the adhesive material on the second electronic component 122.

Accordingly, after one adhesive layer (i.e., the first adhesive layer 231 in FIG. 2) directly touches another adhesive layer (i.e., the second adhesive layer 232 in FIG. 2), the two adhesive layers can be connected by eutectic bonding, so as to form the metallic bonding between two adhesive layers (i.e., the first adhesive layer 231 and the second adhesive layer 232).

Continuing to refer to the embodiment of FIG. 4E, after or before disposing the second electronic component 122, the conductive structures 150 will be disposed on the active surface 122A of the second electronic component 122. After disposing the second electronic component 122, a second encapsulation layer 442 is formed on the first encapsulation layer 441. The second encapsulation layer 442 encapsulates the second conductive pillar 462 and the second electronic component 122, and exposes the second end surface 462e of the second conductive pillar 462.

In particular, the formation of the molding compounds of both the second encapsulation layer 442 and the first encapsulation layer 441 may be the same or different. The formation of the second encapsulation layer 442 may include disposing the molding compound on the first encapsulation layer 441, and curing the molding compound. The molding compound covers the second electronic component 122 and the second conductive pillar 462. Next, the cured molding compound is grinded from its upper surface, so as to form the second encapsulation layer 442 exposing the second end surface 462e. The step of the grinding further can cause that the surface 150s of the conductive structures 150 is exposed by the second encapsulation layer 442, and the second end surface 462e of the second conductive pillar 462 is flush with the surface 150s of the conductive structures 150. In addition, in FIG. 4E, the interface (not labeled) is formed between the first encapsulation layer 441 and the second encapsulation layer 442, where the interface can be seen by an instrument. For example, the interface can be seen by electron microscope.

In addition, in the present embodiment, the area of the interface 461i of the first conductive pillar 461 is equal to the area of the second end surface 462e of the second conductive pillar 462, which the disclosure does not limit. In other embodiment, the area of the interface 461i of the first conductive pillar 461 may be not equal to the second end surface 462e of the second conductive pillar 462. Moreover, the thickness t3 of the first encapsulation layer 441 can be thicker than the thickness t4 of the second encapsulation layer 442.

Referring to FIG. 4F, after the second encapsulation layer 442 (depicted in FIG. 4E) is formed, a second redistribution layer 112 is disposed on the second end surfaces 462e of the second conductive pillars 462. The second redistribution layer 112 is electrically connected to the second electronic component 122 via the conductive structures 150 located on the second electronic component 122. The active surface 121A of the first electronic component 121 and the active surface 122A of the second electronic component 122 face the first redistribution layer 111 and the second redistribution layer 112 respectively.

Referring to FIG. 4G, after disposing the second redistribution layer 112, the holding board 420 (depicted in FIG. 4F) is removed, so as to expose the surface 111s of the first redistribution layer 111. Afterwards, multiple solder balls S1 are disposed on the surface 111s of the first redistribution layer 111. Moreover, a cutting tool 45 is used for dicing the second redistribution layer 112, the first encapsulation layer 441, the second encapsulation layer 442, and the first redistribution layer 111 to perform a singulation process, thereby forming multiple semiconductor package modules 100 as shown in FIG. 1, where the cutting tool 45 may be a rotating blade or a laser beam, but the present disclosure is not limited thereto. So far, the semiconductor package module 100 is basically complete.

The manufacturing method of the semiconductor package module 300 is similar to the manufacturing method of the semiconductor package module 100 as shown in FIG. 4A to FIG. 4G, that is, the method of manufacturing the semiconductor package module 300 includes the steps of the previous embodiment. Hence, the following mainly describes the difference in the manufacturing methods between the semiconductor package modules 300 and 100.

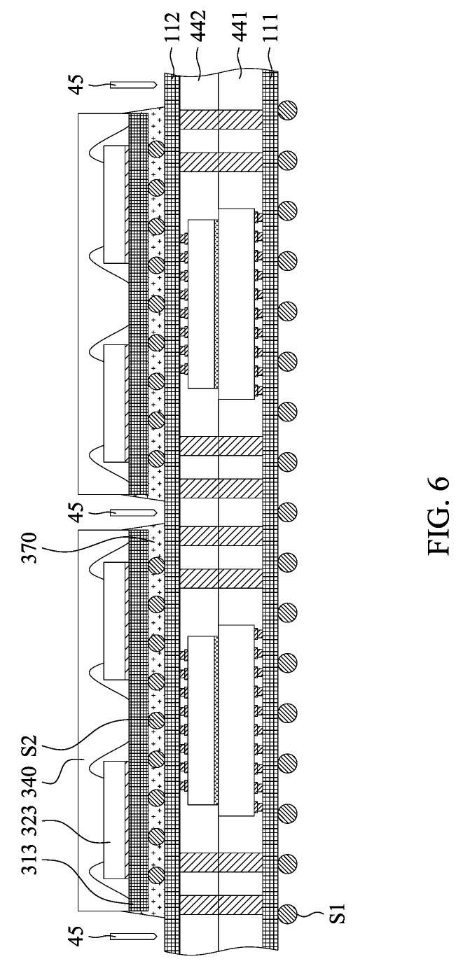

Referring to FIG. 6, the method of manufacturing the semiconductor package module 300 further includes: after disposing the solder balls S1 on the first redistribution layer 111, disposing multiple electronic packaging units 310 as shown in FIG. 3 on the second redistribution layer 112 by using reflow process.

In this embodiment, the electronic packaging unit 310 can be disposed on the second redistribution layer 112 at fast. Then, a filler 370 is formed between the electronic packaging unit 310 and the second redistribution layer 112. The filler 370 may cover the partial side surface of the electronic packaging unit 310, so as to improve the bond between the electronic packaging unit 310 and the second redistribution layer 112. After disposing the filler 370, the singulation process can be performed by using the cutting tool 45 to cut the second redistribution layer 112, the second encapsulation layer 442, the first encapsulation layer 441, and the first redistribution layer 111 in sequence, thereby forming at least one semiconductor package module 300 as shown in FIG. 3. So far, the semiconductor package module 300 is basically complete.

It is worth mentioning that in another embodiment as shown in FIG. 5A to FIG. 5C, the second electronic component 122 is bonded to the second redistribution layer 112 by bumpless scheme. Referring to FIG. 5A, in the manufacturing method of this embodiment, first, at least one second conductive pillar 462 is formed on the holding board 410 (and on the side where the release layer 412 is formed), and at least one second electronic component 122 is disposed on the holding board 410, where the active surface 122A of the second electronic component 122 is connected to the holding board 410 via an adhesive layer (not shown) formed on the release layer 412, or a temporary bonding material. Afterwards, a second encapsulation layer 442 is formed on the holding board 410 (and on the side where the release layer 412 is formed) while the second encapsulation layer 442 exposes the second surface 122s of the second electronic component 122.

Next, the first electronic component 121 is disposed on the second surface 122s of the second electronic component 122, where the first surface 121s of the first electronic component 121 faces the second electronic component 122. In addition, the first conductive pillar 461 may be formed on the second conductive pillar 462. It is particular to note that in this step, an adhesive material 130 can be formed on the first surface 121s of the first electronic component 121 at first, and the first surface 121s of the first electronic component 121 is connected to the second surface 122s of the second electronic component 122 via the adhesive material.

Referring to FIG. 5B, a first encapsulation layer 441 is formed on the second encapsulation layer 442 after the first electronic component 121 is disposed on the second encapsulation layer 442 and the first conductive pillar 461 is formed. Next, the surface 150s of the conductive structures 150 can be exposed on the first encapsulation layer 441 by grinding, and thus, the first end surface 461e of the first conductive pillar 461 is flush with the surface 150s of the conductive structures 150. After the first encapsulation layer 441 is formed, a first redistribution layer 111 is disposed on the first end surface 461e of the first conductive pillar 461. After disposing the first redistribution layer 111, referring to FIG. 5C, the first redistribution layer 111, the first encapsulation layer 441, the second encapsulation layer 442, and the holding board 410 may be inverted, while the holding board 410 (and the release layer 412) will be removed, so as to expose the active surface 122A of the second electronic component 122. Next, a second redistribution layer 112 is formed on the active surface 122A of the second electronic component 122.

The method as shown in FIG. 5A to FIG. 5C can form two encapsulation layers, i.e., the first encapsulation layer 441 and the second encapsulation layer 442. That is to say, the semiconductor package module made by the method as of FIG. 5A to 5C includes two encapsulation layers (the first encapsulation layer 441 and the second encapsulation layer 442). However, in other embodiment, the number of the encapsulation layer included by the semiconductor package module can be only one.

Referring to FIG. 5A and FIG. 5B, the first encapsulation layer 441 and the second encapsulation layer 442 shown in FIG. 5A and FIG. 5B can be replaced by two photoresist layers, such as dry films. Specifically, in other embodiment not shown, in the process of forming the second conductive pillar 462, first, a first photoresist layer, which has been exposed and developed and has multiple openings, is formed on the release layer 412 and directly touches the release layer 412.

Next, using the first photoresist layer as a mask, the second conductive pillars 462 are formed on the release layer 412, where the second conductive pillars 462 are formed in the openings, and protrude a little or do not protrude from the upper surface of the first photoresist layer. Afterwards, the second conductive pillars 462 and the upper surface of the first photoresist layer are grinded, so that the top surface of each second conductive pillar 462 is coplanar to the upper surface of the grinded first photoresist layer.

Afterwards, the first photoresist layer on the release layer 412 remains while a second photoresist layer, which has been exposed and developed, is formed on the first photoresist layer, where the second photoresist layer has multiple openings exposing the top surfaces of the second conductive pillars 462. Next, the first conductive pillars 461 are formed on the first photoresist layer, where the first conductive pillars 461 are formed in the openings of the second photoresist layer respectively. Next, the first photoresist layer and the second photoresist layer are removed while the first conductive pillar 461 and the second conductive pillar 462 on the release layer 412 remain. Afterwards, the first electronic component 121 and the second electronic component 122 are disposed on the release layer 412.

Next, an encapsulation layer which encapsulates the first conductive pillars 461, the second conductive pillars 462, the first electronic component 121, and the second electronic component 122 is formed on the release layer 412 and covers the release layer 412. Afterwards, the steps shown in FIG. 5B and FIG. 5C are performed in sequence. For example, the first end surface 461e of the first conductive pillar 461 is flush with the surface 150s of the conductive structures 150 by grinding. Afterwards, a first redistribution layer 111 is disposed on the first end surface 461e of the first conductive pillar 461. Next, the holding board 410 and the release layer 412 are removed, so as to expose the active surface 122A of the second electronic component 122. Then, a second redistribution layer 112 is formed on the active surface 122A, so as to make a semiconductor package module having a single encapsulation layer.

In other words, in another embodiment, the first encapsulation layer 441 and the second encapsulation layer 442 can be integrally formed into one, and thus there will be no interface formed between the first encapsulation layer 441 and the second encapsulation layer 442. That is. the interface shown in FIG. 5C and formed between the first encapsulation layer 441 and the second encapsulation layer 442 can be omitted.

Therefore, the first electronic component and the second electronic component are disposed between the first redistribution layer and the second redistribution layer in the back-to-back stack (i.e., the active surfaces of both the first electronic component and the second electronic component are arranged back to back to each other), and the first redistribution layer and the second redistribution layer are electrically connected to each other via the conductive pillars, so the planar size (i.e., the size of x-y plane, for example, area) of the semiconductor package module can be reduced while the use of the process material can be reduced, thereby meeting the trend of reducing the sizes (e.g., volumes) of the existing mobile device and the wearable device, and promoting efficient use of resources.

Furthermore, when the adhesive layer located between the first electronic component and the second electronic component has electric conductivity, and the first electronic component is electrically connected to the second electronic component via the adhesive layer, it is advantageous to shorten the path of transmitting electric signals between the first electronic component and the second electronic component, thereby improving the quality of electric signals in the semiconductor package module.

On the other hand, the encapsulation layer used for encapsulating the first electronic component, the second electronic component, and the conductive pillars includes two layers: an upper layer and a lower layer. Since both the upper layer and the lower layer (i.e., including the first encapsulation layer and the second encapsulation layer) in the encapsulation layer may have the same or similar Young’s modulus or the coefficient of thermal expansion, the stress generated by heating the encapsulation layer of the semiconductor package module will be reduced, thereby preventing the semiconductor package module from warpage.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor package module, comprising:
a first redistribution layer;
a first electronic component, disposed on the first redistribution layer and having a first surface away from the first redistribution layer;
an adhesive material, disposed on the first surface of the first electronic component;
a second electronic component, disposed on the adhesive material, wherein the first electronic component is located between the first redistribution layer and the second electronic component, wherein the first electronic component, the adhesive material, and the second electronic component are stacked on each other in a normal direction of the first redistribution layer;
a second redistribution layer, disposed on the second electronic component, wherein the first electronic component and the second electronic component are located between the first redistribution layer and the second redistribution layer, wherein an active surface of the first electronic component and an active surface of the second electronic component face the first redistribution layer and the second redistribution layer respectively;
an encapsulation layer, disposed between the first redistribution layer and the second redistribution layer, and covering the first electronic component and the second electronic component; and
a conductive pillar, connected to the first redistribution layer and the second redistribution layer, and extending from the first redistribution layer to the second redistribution layer through the encapsulation layer, wherein a first part of the conductive pillar is connected to the first redistribution layer, and a second part of the conductive pillar is connected to the second redistribution layer, wherein an interface between the first part and the second part is flush with a plane of the adhesive material.

2. The semiconductor package module of claim 1, wherein the adhesive material is a die attach film (DAF).

3. The semiconductor package module of claim 1, wherein the adhesive material comprises:
a first adhesive layer, disposed on the first electronic component; and
a second adhesive layer, disposed on the second electronic component and located between the first adhesive layer and the second electronic component, wherein the first adhesive layer and the second adhesive layer are connected by a metallic bonding.

4. The semiconductor package module of claim 3, wherein, the first electronic component comprises:
a plurality of first conductive through holes, located in an inside of the first electronic component, wherein the first electronic component is electrically connected to the adhesive material via the first conductive through holes, and the first conductive through holes extend from the active surface of the first electronic component to the first adhesive layer through a main body of the first electronic component,
wherein the second electronic component comprises:
a plurality of second conductive through holes, located in an inside of the second electronic component, wherein the second electronic component is electrically connected to the adhesive material via the second conductive through holes, and the second conductive through holes extend from the active surface of the second electronic component to the second adhesive layer through a main body of the second electronic component.

5. The semiconductor package module of claim 1, wherein the first electronic component and the second electronic component each comprise:
a plurality of pads, located on the active surface of the first electronic component and the active surface of the second electronic component respectively, wherein the first electronic component and the second electronic component are connected to the first redistribution layer and the second redistribution layer respectively via the pads.

6. The semiconductor package module of claim 5, further comprising:
a plurality of conductive structures, disposed on the pads respectively, wherein the pads are electrically connected to at least one of the first redistribution layer and the second redistribution layer via the conductive structures.

7. The semiconductor package module of claim 1, wherein the first part of the conductive pillar has a first section, and the second part of the conductive pillar has a second section, wherein an area of the first section and an area of the second section are not equal.

8. The semiconductor package module of claim 1, wherein the second electronic component has a second surface away from the second redistribution layer, and an area of the second surface is less than an area of the first surface of the first electronic component.

9. The semiconductor package module of claim 8, wherein the adhesive material completely covers the first surface of the first electronic component, and the second electronic component does not cover a zone of the plane of the adhesive material, wherein the encapsulation layer directly touches the zone of the adhesive material.

10. The semiconductor package module of claim 8, wherein the adhesive material completely covers the second surface of the second electronic component, and the adhesive material does not cover a zone of the first surface of the first electronic component.

11. The semiconductor package module of claim 1, wherein the first part of the conductive pillar has a first section, and the second part of the conductive pillar has a second section, wherein an area of the first section and an area of the second section are not equal,
wherein the second electronic component has a second surface away from the second redistribution layer, and an area of the second surface is less than an area of the first surface of the first electronic component.

12. A method of manufacturing a semiconductor package module comprising:
providing a holding board ;
forming at least one first conductive pillar on the holding board;
disposing at least one first electronic component on the holding board, wherein a first surface of the first electronic component is connected to the holding board;
after forming the first conductive pillar and disposing the first electronic component, forming a first encapsulation layer on the holding board, wherein the first encapsulation layer encapsulates the first conductive pillar and the first electronic component and exposes a first end surface of the first conductive pillar;
after forming the first encapsulation layer, disposing a first redistribution layer on the first end surface of the first conductive pillar, wherein the first redistribution layer is electrically connected to the first electronic component, wherein the first conductive pillar has an interface away from the first redistribution layer;
after disposing the first redistribution layer, removing the holding board to expose the first surface of the first electronic component, and exposing the interface of the first conductive pillar;
after removing the holding board, forming a second conductive pillar on the interface of the first conductive pillar;
disposing an adhesive material on a second surface of a second electronic component;
after forming the second conductive pillar, disposing the second electronic component on the first surface of the first electronic component, so that the first electronic component, the adhesive material, and the second electronic component are stacked on each other in a normal direction of the first redistribution layer, and the adhesive material is located between the first electronic component and the second electronic component;
after disposing the second electronic component, forming a second encapsulation layer on the first encapsulation layer, wherein the second encapsulation layer encapsulates the second conductive pillar and the second electronic component, and exposes a second end surface of the second conductive pillar; and
after forming the second encapsulation layer, disposing a second redistribution layer on the second end surface of the second conductive pillar, wherein the second redistribution layer is electrically connected to the second electronic component,
wherein an active surface of the first electronic component and an active surface of the second electronic component face the first redistribution layer and the second redistribution layer respectively.

13. The method of claim 12, further comprising:
before disposing the second electronic component on the first electronic component, disposing an adhesive layer on the first surface of the first electronic component, wherein the adhesive layer and the adhesive material contain metal;
making the adhesive layer on the first electronic component directly touch the adhesive material on the second electronic component; and
after the adhesive layer directly touches the adhesive material, bonding the adhesive layer and the adhesive material by eutectic bonding, so as to from a metallic bonding between the adhesive layer and the adhesive material.

14. The method of claim 12, wherein an area of the interface of the first conductive pillar and an area of the second end surface of the second conductive pillar are not equal.

15. The method of claim 12, further comprising:
before disposing the second electronic component on the first electronic component, disposing an adhesive layer on the first surface of the first electronic component, wherein the adhesive layer and the adhesive material contain metal;
making the adhesive layer on the first electronic component directly touch the adhesive material on the second electronic component; and
after the adhesive layer directly touches the adhesive material, bonding the adhesive layer and the adhesive material by eutectic bonding, so as to from a metallic bonding between the adhesive layer and the adhesive material,
wherein an area of the interface of the first conductive pillar and an area of the second end surface of the second conductive pillar are not equal.
